(19) United States
(12) Patent Application Publication
(10) Pub. No.: US 2026/0251984 A1
(43) Pub. Date: Aug. 27, 2026

(54) Methods And Systems For Metrology System Parameter Calibration Based On A Trained System Parameter Model

(71) Applicant: KLA Corporation, Milpitas, CA (US)

(72) Inventors: Stilian Ivanov Pandev, Santa Clara, CA (US); Min-Yeong Moon, Ann Arbor, MI (US)

(21) Appl. No.: 19/534,601

(22) Filed: Feb. 9, 2026

Related U.S. Application Data
(60) Provisional application No. 63/763,974, filed on Feb. 27, 2025.

(51) Int. Cl. G03F 7/00

(52) U.S. Cl. CPC G03F 7/706845; G03F 7/705; G03F 7/706849; G03F 7/706851

(57) ABSTRACT

Methods and systems for system parameter calibration over time and across a fleet of metrology systems based on a trained system parameter model are described herein. A trained system parameter model enables adjustment of system parameter values to achieve tool-to-tool matching without measurement of the same wafer by each tool in the fleet of measurement tools. A trained, machine-learning based system model is sensitive to errors in the system parameter values across the process variation space of the structures under measurement. System parameter values are adjusted based on the values estimated by the trained system parameter model to remove residual errors on a tool by tool basis, and thus, obtain consistent measurements across a fleet of calibrated tools. In preferred embodiments, a system parameter model estimates values of system parameters based on measurements of one or more metrology targets fabricated on in-line, production wafers.

### CROSS REFERENCE TO RELATED APPLICATION

The present application for patent claims priority under 35 U.S.C. § 119 from U.S. provisional patent application Ser. No. 63/763,974, entitled “Method for Improving Tool Matching By Estimating the Parameters of a System, Calibrating the System and Inline System Parameters Monitoring,” filed Feb. 27, 2025, the subject matter of which is incorporated herein by reference in its entirety.

### TECHNICAL FIELD

The described embodiments relate to metrology systems and methods, and more particularly to methods and systems for improved measurement of parameters characterizing semiconductor structures.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical metrology techniques offer the potential for high throughput measurement without the risk of sample destruction. A number of optical metrology based techniques including scatterometry, reflectometry, and ellipsometry implementations and associated analysis algorithms are commonly used to characterize critical dimensions, film thicknesses, composition and other parameters of nanoscale structures.

In general, the semiconductor industry strives to produce ever smaller devices with increasing structural complexity and material types. Exemplary devices that exhibit such complexity include Gate-All-Around (GAA) Field Effect Transistors (FET), current Dynamic Random Access Memory (DRAM) structures, and current three dimensional flash memory structures.

In one example, GAA FETs manufactured using nanosheet fabrication techniques enable improved device performance and low power consumption, but are difficult to manufacture due to their nanoscale size and complex shape. Nanosheet structures include several material layers. The process of fabricating a nanosheet structure starts by growing a superlattice of Silicon and Silicon Germanium layers. These layers comprise the base structure of a nanosheet. It is critical to measure the characteristics of each layer, e.g., film thickness, to maintain control of the manufacturing process.

In another example, flash memory architectures are transitioning from two dimensional floating-gate architectures to fully three dimensional geometries. In some examples, film stacks and etched structures are very deep (e.g., three or more micrometers in depth) and include an extremely high number of layers (e.g., 400 layers, or more). High aspect ratio structures create challenges for film and CD measurements. The ability to measure the critical dimensions that define the shapes of holes and trenches of these structures is critical to achieve desired performance levels and device yield. The metrology must be capable of measuring the CD of a continuous profile through a deep channel to determine the location of CD variations and inflection points of profile variations.

As devices (e.g., logic and memory devices) move toward smaller nanometer-scale dimensions, characterization becomes more difficult. Devices incorporating complex three-dimensional geometry and materials with diverse physical properties contribute to characterization difficulty. In addition to accurate device characterization, measurement consistency across a range of measurement applications and a fleet of metrology systems tasked with the same measurement objective is also important. If measurement consistency degrades in a manufacturing environment, consistency among processed semiconductor wafers is lost and yield drops to unacceptable levels. Matching measurement results across applications and across multiple systems (i.e., tool-to-tool matching) ensures that measurement results on the same wafer for the same application yield the same result.

A typical calibration approach for model based measurement systems consists of measuring a number of film/substrate systems of known thickness and dielectric function. A regression is performed on machine parameters until the combination of parameters returns the expected values for thickness and/or dielectric function. In one example, a set of film wafers having a silicon dioxide layer on crystalline silicon over a range of thicknesses is measured and a regression is performed on the machine parameters until the machine returns the best match for thickness and/or refraction index for the given set of films. Other examples are described in U.S. Pat. Pub. No. 2004/0073398 entitled, “Methods and Systems for Determining a Critical Dimension and a Thin Film Characteristic of a Specimen,” which is incorporated by reference as if fully set forth herein. This calibration procedure may be applied across a fleet of measurement systems using the same set of wafers. These wafers are sometimes referred to as transfer standards.

Calibration of a fleet of measurement systems using a transfer standard suffers from a number of disadvantages. To obtain high accuracy results, calibration experiments involving the reference wafer must be performed in a carefully controlled environment that matches the environmental conditions in place when the reference wafer was originally characterized. This may be difficult to achieve in a manufacturing environment and lead to loss of consistency among measurement systems. In addition, an expensive reference wafer set must be maintained in the manufacturing environment. Risks of wafer breakage or degradation potentially jeopardize the integrity of the calibration process, and the risks increase when the metrology systems to be calibrated are located in different fabrication facilities.

Machine parameters are often calibrated based on thin film measurements because thin film systems (e.g., silicon dioxide on crystalline silicon) can be manufactured with well-known optical constants, clean interfaces, and low surface roughness that enable measurement of wafer characteristics with a degree of repeatability near the sensitivity of the measurement systems being calibrated. However, the accuracy of a metrology system calibrated based on reference wafers is typically limited to wafers with properties that closely match those of the reference wafer. Thus, the effectiveness of calibration based on thin film measurements may be limited in different measurement applications.

In another approach, system parameter calibration to achieve measurement consistency over time and over different measurement applications is improved by matching measurement spectra across a fleet of metrology systems, rather than specimen parameter values. System parameter values are optimized such that differences between measured spectra generated by a reference system and a target system are minimized for measurements of the same metrology targets. The updated system parameter values are employed in subsequent measurement analyses performed by the target metrology system (e.g., CD measurements, thin-film measurements, CD matching applications, etc.). Further description of this approach is described in U.S. Pat. Nos. 9,857,291 and 10,605,722 assigned to KLA-Tencor Corporation, the contents of each are incorporated herein by reference in their entirety.

In yet another approach, system parameter calibration to achieve measurement consistency over time and over different measurement applications is improved by matching spectral errors across a fleet of metrology systems. System parameter values of a target metrology system are calibrated based on spectral error matching with a reference metrology system. In this approach, the spectral error is difference between the measured spectra and a modeled spectral response of the specimen under measurement. One or more system parameters of a target metrology system are calibrated to minimize the difference between the spectral error associated with the measurement of one or more metrology targets measured by a reference metrology system and the spectral error associated with the measurement of the same metrology targets measured by the target metrology system. Further description of this approach is described in U.S. Pat. No. 10,006,865 assigned to KLA-Tencor Corporation, the content of which is incorporated herein by reference in its entirety.

Matching spectral errors across a fleet of metrology systems with respect to a reference metrology system, e.g., a “golden” tool, introduces some limitations. For example, all the target metrology systems of the fleet must be recalibrated to maintain systematic errors within the desired tolerance when the reference metrology system undergoes hardware changes or maintenance operations. In another example, spectral error data loses significant signal information specific to the measured metrology target because the data is based on the difference between measured and theoretical signal, rather than the measured signals themselves. In another example, system parameter optimization that minimizes spectral errors is complex and computationally burdensome.

Algorithms for calibration of system parameters based on spectral matching and regression are often limited by multiple minima and tradeoffs due to correlation among parameters. Furthermore, inline monitoring of system parameters is not possible using many existing techniques because they require specialized calibration wafer sets, rather than relying on in-line, product wafers. In other examples, inline monitoring of system parameters is impractical using existing techniques due to excessive computational effort.

Maintaining tool measurement consistency over time, across a fleet of similarly configured systems, and over a wide range of measurement applications are core challenges in the development of a metrology system that meets customer requirements of the semi-conductor industry. Process and yield control in both the research and development and manufacturing environments demands consistency of measurement results over on the order of the measurement repeatability. Thus, methods and systems for improved tool-to-tool matching and consistent measurement performance over a wide range of measurement applications are desired.

### SUMMARY

Methods and systems for system parameter calibration over time and across a fleet of metrology systems based on a trained system parameter model are described herein. A trained system parameter model enables rapid systematic error monitoring and recalibration across large numbers of metrology tools. A trained system parameter model enables adjustment of system parameter values to achieve tool-to-tool matching without regression on measurement system model parameters. Thus, computational effort is significantly reduced. Furthermore, a trained system parameter model enables adjustment of system parameter values to achieve tool-to-tool matching without measurement of the same wafer by each tool in the fleet of measurement tools.

System parameter calibration based on a trained system parameter model measures system parameters with respect to a trained, machine-learning based system model. The trained, machine-learning based system model is trained to differentiate variations in the structural features of the samples under measurement and variations in the physical attributes of the measurement system. A trained, machine-learning based system model is sensitive to errors in the system parameter values across the process variation space of the structures under measurement. In this manner, system parameter values are adjusted based on the values estimated by the trained system parameter model to remove residual errors on a tool by tool basis, and thus, obtain consistent measurements across a fleet of calibrated tools.

Training a system parameter model based on a range of different values of structural parameters and a range of different values of system parameters enables the trained system parameter model to accurately estimate values of system parameters based on measurements of any metrology target within the parameter space spanned by the DOE training data.

In preferred embodiments, a system parameter model estimates values of system parameters based on measurements of one or more metrology targets fabricated on in-line, production wafers. This enables system parameter calibration across a fleet of measurement systems based on measurements of metrology targets on in-line, production wafers.

In one aspect, a machine learning based system parameter model is trained based on a set of Design Of Experiments (DOE) measurement data including measurement signals and corresponding values of one or more system parameters.

In some examples, DOE measurement signals are generated synthetically based on a measurement model. The measurement model simulates the measurement signals generated by a nominal metrology tool having the same nominal configuration as each of the fleet of metrology tools to be calibrated. The measurement model includes a geometric and material model of the structure parameterized by numerous structural parameters and a model of the measurement system parameterized by numerous system parameters. The measurement model simulates the measurement signals associated with measurements of each nominal structure under measurement over a range of different values of structural parameters that spans the space of expected structural variations induced by process variation and a range of different values of system parameters that spans the space of expected system parameter variation associated with the fleet of metrology tools to be calibrated.

In some other examples, DOE measurement signals are generated based on actual measurements performed by a reference measurement system having the same nominal configuration of the fleet of metrology tools to be calibrated.

The set of DOE measurement data employed to train a system parameter model includes variations in structural features and variations in system parameter values, i.e., the set of DOE measurement data spans the space of expected structural parameter values and system parameter values.

In some examples, a trained system parameter model is trained to estimate values of one or more system parameters associated with measurements of the same nominal structure. In some other examples, a trained system parameter model is trained to estimate values of one or more system parameters associated with measurements of multiple, different nominal structures.

In another aspect, a trained system parameter model is employed to estimate values of one or more system parameters associated with a measurement system based on actual measurement data collected by the measurement system from one or more metrology targets.

In a further aspect, the trained system parameter model is employed to estimate values of one or more system parameters associated with each measurement system of a fleet of measurement systems based on actual measurement data collected by each measurement system from one or more metrology targets fabricated on in-line, production wafers.

In some embodiments, values of one or more system parameters are estimated by a trained system parameter model based on a single measurement performed by a measurement system. In other embodiments, values of one or more system parameters are estimated by a trained system parameter model based on a set of measurements performed by a measurement system. In these embodiments, the estimated values of one or more system parameters are determined as an average of the values estimated by the trained system parameter model for each of the individual measurements of the set of measurements.

In another aspect, one or more system parameter values associated with a measurement system are adjusted based on the estimated values of the one or more system parameters determined by the trained system parameter model.

In some embodiments, one or more system parameter values associated with a measurement system are adjusted to match the estimated values of the one or more system parameters determined by the trained system parameter model. In some other embodiments, one or more system parameter values associated with a measurement system are incrementally adjusted toward the estimated values of the one or more system parameters determined by the trained system parameter model. The system parameter values implemented by the measurement system are adjusted slowly over time to reduce the difference between the current system parameter values implemented by the measurement system and the values estimated by the trained system parameter model.

In another aspect, a trained system parameter model is employed to estimate values of one or more system parameters based on measurements of structures fabricated on in-line, production wafers to monitor tool health. In some embodiments, values of the one or more system parameters are repeatedly estimated over time based on measurements of different instances of one or more metrology targets to determine a health status of a measurement system. In this manner, an indication of measurement system health is continuously monitored and updated based on in-line measurement data.

The foregoing is a summary and thus contains, by necessity, simplifications, generalizations, and omissions of detail. Consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a simplified diagram illustrative of a metrology system 100 operable in accordance with the methods for system parameter calibration across a fleet of metrology systems as described herein.

FIG. 2 is a diagram illustrative of a system parameter model training engine in one embodiment.

FIG. 3 is a diagram illustrative of system parameter estimation engine in one embodiment.

FIG. 4 is a plot illustrative of the variation in values of a system parameter across seven different measurement systems.

FIG. 5 is a plot illustrative of the variation in values of another system parameter across the seven different measurement systems illustrated in FIG. 4.

FIG. 6 is a flowchart illustrative of a method for system parameter calibration across a fleet of metrology systems as described herein.

### DETAILED DESCRIPTION

Reference will now be made in detail to background examples and some embodiments of the invention, examples of which are illustrated in the accompanying drawings.

Methods and systems for system parameter calibration over time and across a fleet of metrology systems based on a trained system parameter model are described herein. A trained system parameter model enables rapid systematic error monitoring and recalibration across large numbers of metrology tools.

Measurement consistency across multiple measurement applications and across multiple tools depends on properly calibrated sets of machine parameter values for each measurement system. The estimated values of one or more parameters of interest estimated by each of a fleet of metrology tools should match within a desired tolerance. This is referred to as tool-to-tool matching. System model parameters are optimized for each target metrology tool to achieve tool-to-tool matching. Accurate calibration of system parameters improves measurement consistency over time across a fleet of metrology systems and over a range of measurement applications. A trained system parameter model enables adjustment of system parameter values to achieve tool-to-tool matching without regression on measurement system model parameters. Thus, computational effort is significantly reduced. Furthermore, a trained system parameter model enables adjustment of system parameter values to achieve tool-to-tool matching without measurement of the same wafer by each tool in the fleet of measurement tools.

In general, measurement signals detected from a structure under measurement depend on both the structural features of the sample under measurement and the physical attributes of the measurement system. Thus, variations in measured results arise from both variations in the structural features of the sample under measurement and variations in the physical attributes of the measurement system employed to perform the measurements. It follows that measured results across a fleet of measurement systems arise from both variations in the structural features of the samples under measurement and variations in the physical attributes of the measurement systems employed to perform the measurements.

Some traditional calibration techniques rely on measurements of the same samples to mitigate variations in the structural features of the samples under measurement and enhances variations in the physical attributes of the measurement systems. Other techniques employ a “golden” sample having a known, trusted measurement response. This approach also mitigates variations in the structural features of the sample under measurement and enhances variations in the physical attributes of the measurement systems. However, in practice, residual errors remain after the application of these techniques.

System parameter calibration based on a trained system parameter model measures system parameters with respect to a trained, machine-learning based system model that is trained to differentiate variations in the structural features of the samples under measurement and variations in the physical attributes of the measurement system. As a result, it is not necessary to measure the same samples by multiple tools. In preferred embodiments, system parameter values are estimated based on measurements collected from structures manufactured on in-line production wafers, e.g., specialized metrology targets, actual device structures, or both.

A trained, machine-learning based system model is sensitive to errors in the system parameter values across the process variation space of the structures under measurement. In this manner, system parameter values are adjusted based on the values estimated by the trained system parameter model to remove residual errors on a tool by tool basis, and thus, obtain consistent measurements across a fleet of calibrated tools.

Training a system parameter model based on a range of different values of structural parameters and a range of different values of system parameters enables the trained system parameter model to accurately estimate values of system parameters based on measurements of any metrology target within the parameter space spanned by the DOE training data. In preferred embodiments, a system parameter model estimates values of system parameters based on measurements of one or more metrology targets fabricated on in-line, production wafers. This enables system parameter calibration across a fleet of measurement systems based on measurements of metrology targets on in-line, production wafers. Thus, system parameter calibration does not require measurement of the same wafers by each measurement system across the fleet of measurement systems.

In some examples, a trained system parameter model accurately estimates values of system parameters based on measurements of one or more metrology targets. In some examples, the one or more metrology targets are specialized targets, e.g., targets having simplified geometry that can be accurately modelled to enhance accuracy of the DOE data set. In some examples, the one or more metrology targets are actual device structures fabricated on a wafer. In some examples, the one or more metrology targets are fabricated within the scribe line area of a wafer. In some examples, the one or more metrology targets are fabricated within the active device area of a wafer. In general, a trained system parameter model accurately estimates values of system parameters based on measurements of one or more metrology targets that are not accurately measured by a reference metrology system, i.e., it is not necessary that specific dimensions or material properties of the metrology targets have known values. Reference measurements of metrology targets are not required because the input to a trained system parameter model is measurement signals, not specific dimensions or material properties. Furthermore, the training of a system parameter model is based on measurement signals, not specific dimensions or material properties.

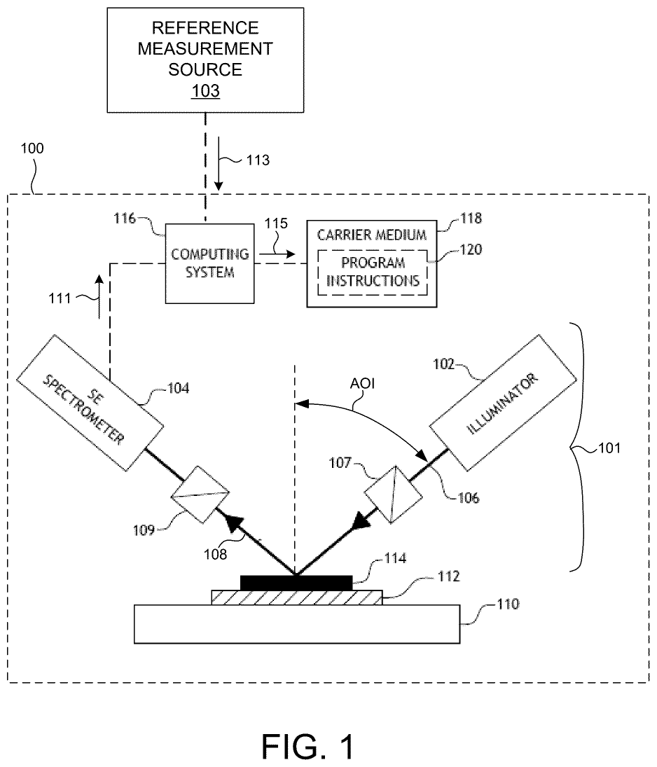

FIG. 1 illustrates a metrology system 100 for measuring characteristics of a semiconductor wafer in accordance with the exemplary methods presented herein. As shown in FIG. 1, the system 100 may be used to perform spectroscopic ellipsometry measurements of one or more structures 114 of a semiconductor wafer 112 disposed on a wafer positioning system 110. In this aspect, the system 100 may include a spectroscopic ellipsometer (SE) 101 equipped with an illuminator 102 and a spectrometer 104. The illuminator 102 of the system 100 is configured to generate and direct illumination of a selected wavelength range (e.g., 150-850 nm, 190-850 nm, 240-850 nm, etc.) to the structure 114 disposed on the surface of the semiconductor wafer 112. In turn, the spectrometer 104 is configured to receive illumination reflected from the surface of the semiconductor wafer 112. It is further noted that the light emerging from the illuminator 102 is polarized using a polarization state generator 107 to produce a polarized illumination beam 106. The radiation reflected by the structure 114 disposed on the wafer 112 is passed through a polarization state analyzer 109 and to the spectrometer 104. The radiation received by the spectrometer 104 in the collection beam 108 is analyzed with regard to polarization state, allowing for spectral analysis by the spectrometer of radiation passed by the analyzer.

The one or more computing systems 116 are communicatively coupled to the spectrometer 104. In one aspect, the one or more computing systems 116 are configured to receive measurement data 111 associated with a measurement of the structure 114 of specimen 112. In one example, the measurement data 111 includes an indication of the measured spectral response of the specimen by target measurement system 100 based on the one or more sampling processes from the spectrometer 104.

As illustrated in FIG. 1, a beam of broadband radiation from illuminator 102 is linearly polarized in polarization state generator 107, and the linearly polarized beam is then incident on specimen 112. After reflection from specimen 112, the beam propagates toward polarization state analyzer 109 with a changed polarization state. In some examples, the reflected beam has elliptical polarization. The reflected beam propagates through polarization state analyzer 109 into spectrometer 104. In spectrometer 104, the beam components having different wavelengths are refracted (e.g., in a prism spectrometer) or diffracted (e.g., in a grating spectrometer) in different directions to different detectors. The detectors may be a linear array of photodiodes, with each photodiode measuring radiation in a different wavelength range.

In one example, computing system 116 receives the measured data (e.g., raw measurement data) from each detector, and is programmed with software for processing the data it receives in an appropriate manner. The measured spectral response of a specimen may be determined by analyzing the changes in polarization of radiation reflected from the sample in response to incident radiation having known polarization state in any number of ways known in the art.

Any of polarization state generator 107 and polarization state analyzer 109 may be configured to rotate about their optical axis during a measurement operation. In some examples, computing system 116 is programmed to generate control signals to control the angular orientation of polarization state generator 107 and/or polarization state analyzer 109, or other elements of the system 100 (e.g., wafer positioning system 110 upon which specimen 112 rests). Computing system 116 may also receive data indicative of the angular orientation of polarization state analyzer 109 from an analyzer position sensor associated with polarization state analyzer 109. Similarly, computing system 116 may also receive data indicative of the angular orientation of polarization state generator 107 from a polarizer position sensor associated with polarization state generator 107. Computing system 116 may be programmed with software for processing such orientation data in an appropriate manner.

In one embodiment, the polarization state generator 107 is a linear polarizer that is controlled so that it rotates at a constant speed, and the polarization state analyzer is a linear polarizer that is not rotating (“the analyzer”). The signal received at each detector of spectrometer 104 (i.e., the raw measurement data) will be a time-varying intensity given by:

$$I ( t ) = {I}_{0} [ 1 + αcos ( 2 ω t - {P}_{0} ) + βsin ( 2 ω t - {P}_{0} ) ] \qquad ( 1 )$$

where I₀ is a constant that depends on the intensity of radiation emitted by illuminator 102, ω is the angular velocity of polarization state generator 107, P₀ is the angle between the optical axis of polarization state generator 107 and the plane of incidence (e.g., the plane of FIG. 1) at an initial time (t=0), and spectral signals, α and β, are values defined as follows:

$$α = [ {tan}^{2} Ψ - {tan}^{2} ( A - {A}_{0} ) ] / [ {tan}^{2} Ψ + {tan}^{2} ( A - {A}_{0} ) ] \qquad ( 2 )$$

$$β = [ 2 ( tanΨ ) ( cosΔ ) ( tan A - {A}_{0} ) ] / [ {tan}^{2} Ψ + {tan}^{2} ( A - {A}_{0} ) ] \qquad ( 3 )$$

where tan(Ψ) is the amplitude of the complex ratio of the p and s reflection coefficients of the sample and Δ is the phase of the complex ratio of the p and s reflection coefficients of the sample. The “p” component denotes the component of polarized radiation whose electrical field is in the plane of FIG. 1, and “s” denotes the component of polarized radiation whose electrical field is perpendicular to the plane of FIG. 1. A is the nominal analyzer angle (e.g., a measured value of the orientation angle supplied, for example, from the above-mentioned analyzer position sensor associated with polarization state analyzer 109). A₀ is the offset of the actual orientation angle of polarization state analyzer 109 from the reading “A” (e.g., due to mechanical misalignment, A₀ may be non-zero).

In general, the spectral response of a specimen to a measurement is calculated by the metrology system based on functions of spectrometer data, S, and a subset of system parameter values, P_{sys1}, as illustrated by equations (4) and (5)

$${α}_{meas} = m ( {P}_{sys 1} , S ) \qquad ( 4 )$$

$${β}_{meas} = m ( {P}_{sys 1} , S ) \qquad ( 5 )$$

The subset of system parameter values, P_{sys1}, are those system parameters needed to determine the spectral response of the specimen to the measurement performed by the metrology system.

For the embodiment described with reference to FIG. 1, the subset of system parameters, P_{sys1}, includes the measurement system parameters of equations (1)-(3). Values of αₘₑₐₛ and βₘₑₐₛ are determined based on a measurement of a particular specimen by metrology system 100 and a subset of system parameter values as described by equations (1)-(3).

In general, ellipsometry is an indirect method of measuring physical properties of the specimen under measurement. In most cases, the measured values (e.g., αₘₑₐₛ and βₘₑₐₛ) cannot be used to directly determine the physical properties of the specimen. The nominal measurement process consists of formulating a measurement model that estimates the measured values (e.g., αₘₑₐₛ and βₘₑₐₛ) for a given measurement scenario. The measurement model characterizes the interaction of the specimen with the measurement system. The measurement model includes a parameterization of the structure (e.g., film thicknesses, critical dimensions, etc.) and the measurement system (e.g., wavelengths, angles of incidence, polarization angles, etc.). As illustrated in equations (6) and (7), the measurement model includes parameters associated with the measurement system (P_{sys}) and the specimen (P_{specimen}).

$${α}_{model} = f ( {P}_{sys} , {P}_{specimen} ) \qquad ( 6 )$$

$${β}_{model} = g ( {P}_{sys} , {P}_{specimen} ) \qquad ( 7 )$$

Measurement system parameters are parameters used to characterize the metrology tool (e.g., ellipsometer 101), and may include some or all of the subset of system parameters described with reference to equations (4) and (5). Exemplary machine parameters include angle of incidence (AOI), analyzer angle (A₀), polarizer angle (P₀), illumination wavelength, numerical aperture (NA), etc. Specimen parameters are parameters used to characterize the specimen (e.g., specimen 112 including structures 114). For a thin film specimen, exemplary specimen parameters include refractive index, dielectric function tensor, nominal layer thickness of all layers, layer sequence, etc. For measurement purposes, the machine parameters are treated as known, fixed parameters and the specimen parameters are treated as unknown, floating parameters. The floating parameters are resolved by an iterative process (e.g., regression) that produces the best fit between theoretical predictions and experimental data. The unknown specimen parameters, P_{specimen}, are varied and the model output values (e.g., α_{model} and β_{model}) are calculated until a set of specimen parameter values are determined that results in a close match between the model output values and the experimentally measured values (e.g., αₘₑₐₛ and βₘₑₐₛ).

In a model based measurement application such as spectroscopic ellipsometry, a regression process (e.g., ordinary least squares regression) is employed to identify specimen parameter values that minimize the differences between the model output values and the experimentally measured values for a fixed set of machine parameter values.

In a further embodiment, measurement system 100 includes one or more computing systems 116 employed to perform calibration of the system parameter values of the measurement system 100 in accordance with the methods described herein.

In addition, in some embodiments, the one or more computing systems 116 are further configured to receive training data 113 including measurement data and corresponding values of one or more system parameters from a reference measurement source 103. In one example, training data 113 includes simulated spectra associated with a simulated measurement of a structure generated by a measurement simulation engine, and the corresponding values of one or more system parameters associated with the measurement simulation. In another example, measurement data 113 includes measured spectra associated with an actual measurement of a structure by a reference metrology system, and corresponding, known values of one or more system parameters characterizing the reference metrology system. In some examples, measurement data 113 is stored in carrier medium 118 and retrieved by computing system 116.

In one aspect, a machine learning based system parameter model is trained based on a set of Design Of Experiments (DOE) measurement data including measurement signals and corresponding values of one or more system parameters. In some examples, DOE measurement signals are generated synthetically based on a measurement model. The measurement model simulates the measurement signals generated by a nominal metrology tool having the same nominal configuration as each of the fleet of metrology tools to be calibrated. The measurement model includes a geometric and material model of the structure parameterized by numerous structural parameters and a model of the measurement system parameterized by numerous system parameters. The measurement model simulates the measurement signals associated with measurements of each nominal structure under measurement over a range of different values of structural parameters that spans the space of expected structural variations induced by process variation and a range of different values of system parameters that spans the space of expected system parameter variation associated with the fleet of metrology tools to be calibrated.

In some other examples, DOE measurement signals are generated based on actual measurements performed by a reference measurement system having the same nominal configuration of the fleet of metrology tools to be calibrated. In preferred embodiments, DOE measurement signals are generated synthetically based on a measurement model to generate large sets of training data quickly and at relatively low cost. In addition, it is often challenging to measure actual system parameter values associated with a reference measurement system with sufficient accuracy.

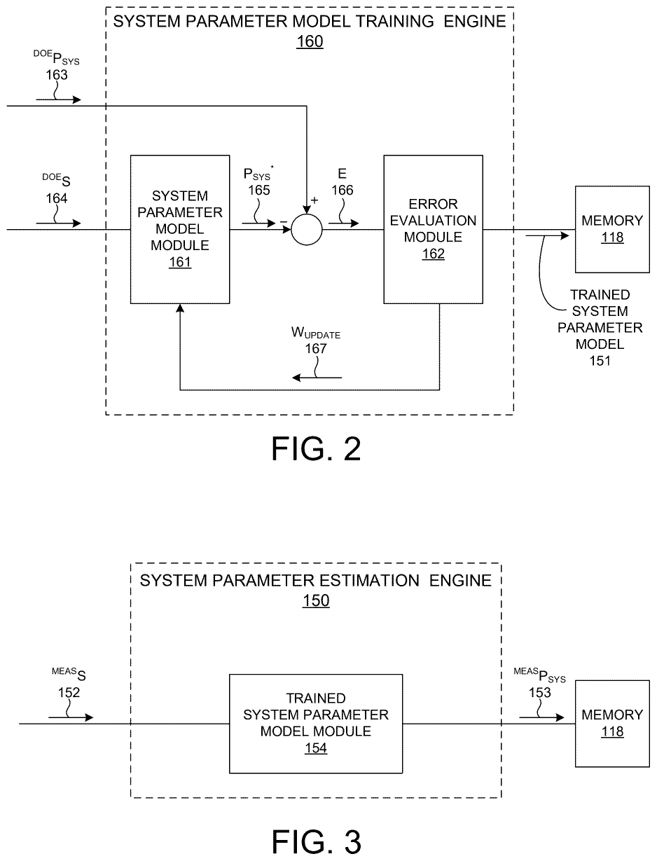

In one embodiment, computing system 116 is configured as a system parameter model training engine 160 as illustrated in FIG. 2.

As depicted in FIG. 2, system parameter model training engine 160 includes system parameter model module 161 and error evaluation module 162. System parameter model module 161 includes a system parameter model being trained. System parameter model training engine 160 receives a DOE training data set including a set of DOE measurement signals, ^{DOE}S 164, and corresponding values of one or more system parameters, ^{DOE}P_{SYS} 163. System parameter model module 161 receives DOE measurement signals, ^{DOE}S 164, associated with the measurement of one or more metrology targets by a measurement system at multiple different system parameter values and multiple, different values of structural parameters characterizing the structures under measurement. In preferred embodiments, the set of DOE measurement signals and corresponding system parameter values are generated by a measurement model based simulation. The system parameter model of system parameter model module 161 generates estimated values of one or more system parameters, P_{SYS}* 165, associated with each measurement of the set of DOE measurement signals, ^{DOE}S 164. System parameter model training engine 160 generates error signals, E 166, based on a difference between each of the estimated values of the one or more system parameters, P_{sys}* 165, and the corresponding values of one or more system parameters, ^{DOE}P_{SYS} 163. Error evaluation module 162 generates updated values of weighting parameters, W_{UPDATE} 167, based on the error signals, E 166. Error evaluation module 162 generates updated values of weighting parameters, W_{UPDATE} 167, to minimize error signals, E 166. In the next iteration of model training, new estimated values of one or more system parameters, P_{SYS}* 165, are generated by system parameter model module 161 based on the updated values of the weighting parameters 167 generated in the previous iteration. The training process continues until the differences between the estimated values of one or more system parameters, P_{SYS}* 165 and the corresponding values of one or more system parameters, ^{DOE}P_{SYS} 163 are acceptably small. At this point, the trained system parameter model 151 is stored in a memory, e.g., memory 118.

The set of DOE measurement data employed to train a system parameter model includes variations in structural features and variations in system parameter values, i.e., the set of DOE measurement data spans the space of expected structural parameter values and system parameter values. In some examples, a trained system parameter model is trained to estimate values of one or more system parameters associated with measurements of the same nominal structure, e.g., a particular thin film thickness, a particular critical dimension of a particular Gate-All-Around (GAA) structure, etc. In these examples, the system parameter model is trained based on a set of DOE measurement data that spans the space of expected system parameter values and space of expected values of the structural parameter values associated with the particular structure under measurement, e.g., a particular thin film thickness, a particular critical dimension of a particular Gate-All-Around (GAA) structure, etc.

In some other examples, a trained system parameter model is trained to estimate values of one or more system parameters associated with measurements of multiple, different nominal structures, e.g., multiple, different thin film structures, multiple, different GAA structures, etc. In some examples, the multiple, different nominal structures are fabricated on different wafer layers. In these examples, the system parameter model is trained based on a set of DOE measurement data that spans the space of expected system parameter values and space of expected values of the structural parameter values associated with the different structures under measurement.

Semiconductor structures employed to train a machine learning based system parameter model include, but not limited to nanosheet logic structures, DRAM structures, 3D Flash memory structures, etc. Fleets of metrology systems matched using a trained machine learning based system parameter model are employed to measure structural and material characteristics (e.g., material composition, dimensional characteristics of structures and films, etc.) associated with different semiconductor fabrication processes.

In another aspect, a trained system parameter model is employed to estimate values of one or more system parameters associated with a measurement system based on actual measurement data collected by the measurement system from one or more metrology targets.

In one aspect, computing system 116 is configured as a system parameter estimation engine 150 as illustrated in FIG. 3. System parameter estimation engine 150 employs a trained system parameter model 151 that enables system parameter monitoring and calibration across a fleet of metrology tools.

As depicted in FIG. 3, system parameter estimation engine 150 includes a system parameter model module 154 including a trained system parameter model 151. System parameter model module 154 receives measurement signals, ^{MEAS}S 152, associated with the measurement of a metrology target by a measurement system. System parameter model 151 generates estimated values of one or more system parameters, ^{MEAS}P_{SYS} 153, based on measurement signals, ^{MEAS}S 152. As described hereinbefore, trained system parameter model 151 is a trained machine learning based model, e.g., neural network model, etc. The estimated values of one or more system parameters, ^{MEAS}P_{SYS} 153, are stored in a memory, e.g., memory 118.

In a further aspect, the trained system parameter model is employed to estimate values of one or more system parameters associated with each measurement system of a fleet of measurement systems based on actual measurement data collected by each measurement system from one or more metrology targets fabricated on in-line, production wafers. The measurement systems of the fleet of measurement systems are identical in their nominal configuration, i.e., the same nominal optical configuration. Each differs in the values of the system parameters employed to perform measurements of semiconductor structures. Each measurement system of the fleet of measurement system is tasked with the same measurement application, i.e., each of the measurement systems are employed to measure the same nominal structures.

In some embodiments, values of one or more system parameters are estimated by a trained system parameter model based on a single measurement performed by a measurement system, i.e., a measurement of a metrology target on a wafer. In these embodiments, the estimated values of one or more system parameters are the values estimated by the trained system parameter model for the single measurement.

In other embodiments, values of one or more system parameters are estimated by a trained system parameter model based on a set of measurements performed by a measurement system. In these embodiments, the estimated values of one or more system parameters are determined as an average of the values estimated by the trained system parameter model for each of the individual measurements of the set of measurements. In some examples, the set of measurements includes measurements of multiple instances of the same metrology target fabricated on one or more wafers. In some examples, the set of measurements includes measurements of one or more instances of multiple, different metrology targets fabricated on one or more wafers.

In another aspect, one or more system parameter values associated with a measurement system are adjusted based on the estimated values of the one or more system parameters determined by the trained system parameter model.

In general, values of one or more system parameters are estimated by the trained system parameter model based on measurements performed by each measurement system of a fleet of measurement systems. Similarly, the values of one or more system parameters associated with each measurement system are adjusted based on the estimated values determined by the trained system parameter model corresponding to measurements performed by each measurement system.

In some embodiments, one or more system parameter values associated with a measurement system are adjusted to match the estimated values of the one or more system parameters determined by the trained system parameter model, e.g., based on an average of a set of measurement as described hereinbefore.

In some embodiments, one or more system parameter values associated with a measurement system are incrementally adjusted toward the estimated values of the one or more system parameters determined by the trained system parameter model. In these embodiments, the estimated values of one or more system parameters determined by a trained system parameter model are employed to characterize the magnitude and direction of mismatch between the current system parameter values implemented by the measurement system and the values estimated by the trained system parameter model. The system parameter values implemented by the measurement system are adjusted slowly over time to reduce the difference between the current system parameter values implemented by the measurement system and the values estimated by the trained system parameter model.

In another aspect, a trained system parameter model is employed to estimate values of one or more system parameters based on measurements of structures fabricated on in-line, production wafers to monitor tool health. In some embodiments, values of the one or more system parameters are repeatedly estimated over time based on measurements of different instances of one or more metrology targets to determine a health status of a measurement system. In some examples, a tool health metric is determined based on the values of the one or more system parameters repeatedly estimated over time. Exemplary tool health metrics include, but are not limited to, the range, average value, standard deviation, etc., of the set of estimated values of the system parameters repeatedly estimated over time.

In this manner, an indication of measurement system health is continuously monitored and updated based on in-line measurement data. In some examples, trends in measurement system health are employed to schedule periodic maintenance, recalibration events, etc. In another example, an excessive range of values of a system parameter indicates a problem with a particular component of a metrology tool. In another example, a drift in values of a system parameter indicates a problem with a particular component of a metrology tool. In another example, a large excursion in values of a system parameter from a long term average and standard deviation across one metrology tool or across a fleet of metrology tools indicates a problem with a particular component of a particular metrology tool.

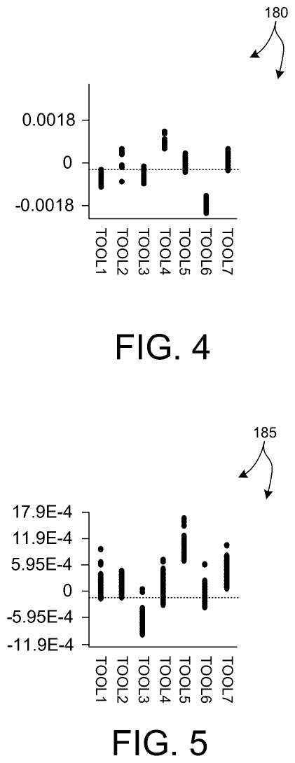

FIG. 4 is a plot 180 illustrative of the variation in values of a system parameter across seven different measurement systems. As depicted in FIG. 4, the value of a system parameter is plotted along the vertical axis and the identity of each metrology tool is plotted along the horizontal axis. For each tool plotted along the horizontal axis, i.e. tools 1-7, the value of a system parameter estimated by a trained system parameter model for each of a large number of measurements is plotted along the vertical axis. As illustrated in FIG. 4, the mean value and standard deviation of estimated values of the system parameter are different for each measurement system.

FIG. 5 is a plot 185 illustrative of the variation in values of another system parameter across seven different measurement systems. As depicted in FIG. 5, the value of the system parameter is plotted along the vertical axis and the identity of each metrology tool is plotted along the horizontal axis. For each tool plotted along the horizontal axis, i.e. tools 1-7, the value of a system parameter estimated by a trained system parameter model for each of a large number of measurements is plotted along the vertical axis. As illustrated in FIG. 5, the mean value and standard deviation of estimated values of the system parameter are different for each measurement system. Furthermore, the mean value and standard deviation of estimated values of the system parameter depicted in FIG. 4 are different from the mean value and standard deviation of estimated values of the system parameter depicted in FIG. 5.

The application of the aforementioned methods is not limited to a particular spectroscopic signal, i.e., the methods are applicable regardless of the spectroscopic signal under consideration, e.g., cos(Δ), tan(Ψ), α and β harmonic signals, Mueller Matrix coefficient signals, etc. In one example, the indications of the measured spectral response are αₘₑₐₛ and βₘₑₐₛ values derived from measurement data by methods known in the art as discussed hereinbefore with reference to equations (1)-(5). In other examples, other indications of the measured spectral response may be contemplated (e.g., tan Ψ and Δ, etc.). The aforementioned spectral response indications are provided by way of non-limiting example. Other indications or combinations of indications may be contemplated. It is important to note that a spectral indication is based on the spectral response of the specimen, not specific metrics (e.g., film thickness, index of refraction, dielectric constants, etc.) that may be derived from the spectral response of the specimen.

Furthermore, the application of the aforementioned methods is not limited to a particular range of measured wavelengths, i.e., the methods are application regardless of the range of measured wavelengths, e.g., range including any of VUV, UV, visible, near-infrared, and mid-infrared wavelengths.

It should be further noted that the application of the aforementioned methods is not limited to spectroscopic ellipsometry. In general, the methods and systems for system parameter calibration may be applied to improve tool-to-tool matching and measurement stability of any measurement tool, in both on-line or off-line implementations. Such systems are employed to measure structural and material characteristics (e.g., material composition, dimensional characteristics of structures and films, etc.) associated with different semiconductor fabrication processes.

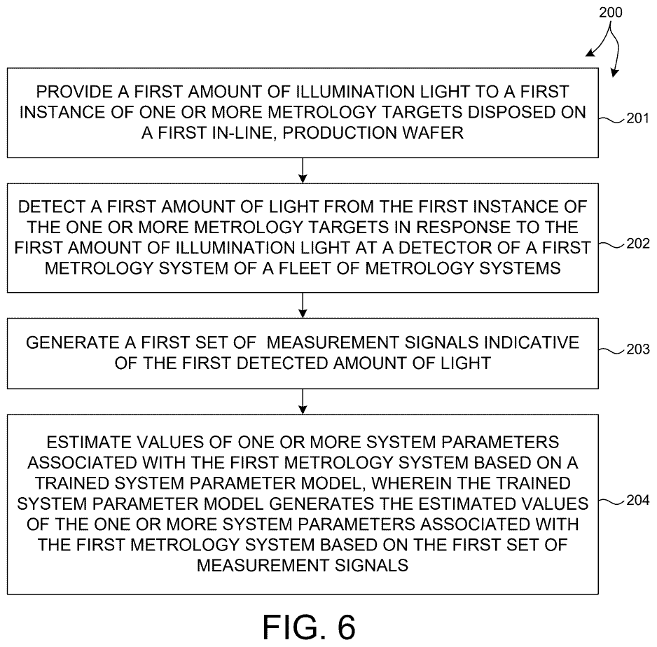

FIG. 6 illustrates a method 200 suitable for implementation by the metrology system 100 of the present invention. In one aspect, it is recognized that data processing blocks of method 200 may be carried out via a pre-programmed algorithm executed by one or more processors of computing system 116. While the following description is presented in the context of metrology system 100, it is recognized herein that the particular structural aspects of metrology system 100 do not represent limitations and should be interpreted as illustrative only.

In block 201, an amount of illumination light is provided to a first instance of one or more metrology targets disposed on a first in-line, production wafer.

In block 202, an amount of light from the first instance of the one or more metrology targets is detected in response to the amount of illumination light at a detector of a metrology system.

In block 203, a set of measurement signals indicative of the detected amount of light is generated.

In block 204, values of one or more system parameters associated with the metrology system are estimated based on a trained system parameter model. The trained system parameter model generates the estimated values of the one or more system parameters based on the set of measurement signals.

It should be recognized that the various elements described throughout the present disclosure may be carried out by a single computer system 116 or, alternatively, a multiple computer system 116. Moreover, different subsystems of the system 100, such as the spectroscopic ellipsometer 101, may include a computer system suitable for carrying out at least a portion of the steps described herein. Therefore, the aforementioned description should not be interpreted as a limitation on the present invention but merely an illustration. Further, the one or more computing systems 116 may be configured to perform any other step(s) of any of the method embodiments described herein. Moreover, some or all of the one or more computing systems 116 may be located remotely from the site of wafer measurement. For example, elements of computing system 116 configured to perform any of the methods described herein may be located at another facility remotely located from the site of where the wafer is measured.

In this regard, there is no requirement that measurement acquisition and subsequent analysis of the measurement data need be contemporaneous or performed in spatial proximity. For instance, spectral data may be stored in memory for analysis at a later time. In another instance, spectral results may be obtained and transmitted to a computing system located at a remote location for analysis.

In addition, the computer system 116 may be communicatively coupled to the spectrometer 104, the illuminator subsystem 102 of the ellipsometer 101, or the reference measurement source 103 (e.g., an external memory, a reference metrology system, etc.) in any manner known in the art. For example, the one or more computing systems 116 may be coupled to a computing system of the spectrometer 104 of the ellipsometer 101 and a computing system of the illuminator subsystem 102. In another example, the spectrometer 104 and the illuminator 102 may be controlled by a single computer system. In this manner, the computer system 116 of the system 100 may be coupled to a single ellipsometer computer system.

The computer system 116 of the system 100 may be configured to receive and/or acquire data or information from the subsystems of the system (e.g., spectrometer 104, illuminator 102, and the like) by a transmission medium that may include wireline and/or wireless portions. In this manner, the transmission medium may serve as a data link between the computer system 116 and other subsystems of the system 100. Further, the computing system 116 may be configured to receive measurement data via a storage medium (i.e., memory). For instance, the spectral results obtained using a spectrometer of ellipsometer 101 may be stored in a permanent or semi-permanent memory device (not shown). In this regard, the spectral results may be imported from an external system.

Moreover, the computer system 116 may send data to external systems via a transmission medium. The computer system 116 of the system 100 may be configured to receive and/or acquire data or information from other systems (e.g., inspection results from an inspection system or metrology results from a metrology system) by a transmission medium that may include wireline and/or wireless portions. In this manner, the transmission medium may serve as a data link between the computer system 116 and other subsystems of the system 100. Moreover, the computer system 116 may send data to external systems via a transmission medium.

The computing system 116 may include, but is not limited to, a personal computer system, cloud-based computer system, mainframe computer system, workstation, image computer, parallel processor, or any other device known in the art. In general, the term “computing system” may be broadly defined to encompass any device having one or more processors, which execute instructions from a memory medium.

Program instructions 120 implementing methods such as those described herein may be transmitted over or stored on carrier medium 118. The carrier medium may be a transmission medium such as a wire, cable, or wireless transmission link. The carrier medium may also include a computer-readable medium such as a read-only memory, a random access memory, a solid-state memory, a magnetic or optical disk, or a magnetic tape.

The embodiments of the system 100 illustrated in FIG. 1 may be further configured as described herein. In addition, the system 100 may be configured to perform any other block(s) of any of the method embodiment(s) described herein.

The terms reference metrology system and target metrology system generally refer to a metrology system status (i.e., target) that requires adaptation of the system parameters to obtain measurement consistency with another metrology system status (i.e., reference). In this manner, the target is being calibrated with respect to the reference.

In some examples, the target metrology system and the reference metrology system are different tools. For example, in a manufacturing context, it may be advantageous to have a fleet of metrology systems each calibrated to a single reference metrology system. In this manner, each of the fleet of metrology systems is consistent with a single reference tool. In another example, it may be advantageous to have a one or more metrology systems each calibrated to a fleet average of many metrology systems. In this manner, each of the metrology systems is consistent with an entire fleet of metrology tools. In another example, reference and target systems are the same system measured at different times (e.g., before and after a hardware maintenance operation).

In general, any suitable metrology system may be employed as the trusted metrology system within the scope of this patent document. For example, any of a beam profile reflectometer, a reflectometer, and an appropriate x-ray based metrology system may be employed as a trusted metrology system. In addition, there is no requirement that the trusted metrology system be integrated with the target metrology tool. In some examples, the trusted metrology system may be a separate metrology tool.

In a further aspect, the optimized subset of system parameters is loaded onto the target metrology system. These optimized parameters are subsequently used for further measurement analyses involving the measurement model (e.g., measurement model described with reference to equations (6) and (7)). In some examples, critical dimension (CD) measurements are performed by the target measurement system using the optimized subset of system parameters. For example, a structural parameter of the calibration specimen may be estimated based on a regression of the updated target system measurement model on the spectral data associated with the measurement of the calibration specimen. In this example, the spectral data is also calculated based on the underlying raw measurement data and the optimized subset of system parameters.

In another further aspect, the composite measurement matching signals driving the training of the error evaluation model can be weighted differently. In one example, the relative weightings are based on measurement sensitivity to any of multiple measurement sites, multiple measurement samples, multiple illumination wavelengths, and multiple measurement subsystems. In this manner, specific measurement sites, samples, subsystems, or illumination wavelengths with particularly high measurement sensitivity can be emphasized. In another example, the relative weightings are based on measurement noise associated any of multiple measurement sites, multiple measurement samples, multiple illumination wavelengths, and multiple measurement subsystems. In this manner, specific measurement sites, samples, subsystems, or illumination wavelengths with particularly high measurement noise can be de-emphasized.

Metrology systems configured to measure geometry and material properties of dielectric and metallic films and structures may employ the methods described herein. Such measurements include, by way of non-limiting example, film properties and dimensions, CD, overlay, and composition measurements. Such metrology systems may include any number of illumination sources, including, but not limited to lamps, lasers, laser driven sources, x-ray sources and EUV sources. Such metrology systems may employ an number of measurement technologies, including, but not limited to all implementations of ellipsometers (including broadband spectroscopic or single wavelength, single- or multi-angle, or angle-resolved, with fixed or rotating polarizers and compensators), all implementations of reflectometers (including spectroscopic or single wavelength, single- or multi-angle, or angle-resolved), all implementations of scatterometers, differential measurements, such as interferometers, and x-ray based metrologies.

As described herein, the term “metrology system” includes any system employed at least in part to characterize a specimen in any aspect. Exemplary terms used in the art may include a “defect inspection” system or an “inspection” system. However, such terms of art do not limit the scope of the term “metrology system” as described herein. In addition, the metrology system 100 may be configured for inspection of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on differences in error spectra between a reference and a target metrology tool.

Various embodiments are described herein for a semiconductor processing system (e.g., a metrology system or a lithography system) that may be used for processing a specimen. The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate.

One or more layers may be formed upon a wafer. For example, such layers may include, but are not limited to, a resist, a dielectric material, a conductive material, and a semiconductive material. Many different types of such layers are known in the art, and the term wafer as used herein is intended to encompass a wafer on which all types of such layers may be formed.

One or more layers formed on a wafer may be “patterned” or “unpatterned.” For example, a wafer may include a plurality of dies having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

A typical semiconductor process includes wafer processing by lot. As used herein a “lot” is a group of wafers (e.g., group of 25 wafers) which are processed together. Each wafer in the lot is comprised of many exposure fields from lithography processing tools (e.g. steppers, scanners, etc.). Within each field may exist multiple die. A die is the functional unit which eventually becomes a single chip. One or more layers formed on a wafer may be patterned or unpatterned. For example, a wafer may include a plurality of dies, each having repeatable patterned features. Formation and processing of such layers of material may ultimately result in completed devices. Many different types of devices may be formed on a wafer, and the term wafer as used herein is intended to encompass a wafer on which any type of device known in the art is being fabricated.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as quartz. A reticle may be disposed above a resist-covered wafer during an exposure step of a lithography process such that the pattern on the reticle may be transferred to the resist.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A method comprising:
providing a first amount of illumination light to a first instance of one or more metrology targets disposed on a first in-line, production wafer;
detecting a first amount of light from the first instance of the one or more metrology targets in response to the first amount of illumination light at a detector of a first metrology system of a fleet of metrology systems;
generating a first set of measurement signals indicative of the first detected amount of light; and
estimating values of one or more system parameters associated with the first metrology system based on a trained system parameter model, wherein the trained system parameter model generates the estimated values of the one or more system parameters associated with the first metrology system based on the first set of measurement signals.

2. The method of claim 1, further comprising:
providing a second amount of illumination light to a second instance of the one or more metrology targets disposed on a second in-line, production wafer;
detecting a second amount of light from the second instance of the one or more metrology targets in response to the second amount of illumination light at a detector of a second metrology system of the fleet of metrology systems;
generating a second set of measurement signals indicative of the second detected amount of light; and
estimating values of one or more system parameters associated with the second metrology system based on the trained system parameter model, wherein the trained system parameter model generates the estimated values of the one or more system parameters associated with the second metrology system based on the second set of measurement signals.

3. The method of claim 1, further comprising:
training the trained system parameter model, wherein the training is based on a set of Design Of Experiments (DOE) measurement data corresponding to the one or more metrology targets including multiple sets of measurement signals and corresponding sets of values of the one or more system parameters associated with each metrology system of the fleet of metrology systems.

4. The method of claim 3, wherein the DOE measurement signals are generated by simulation of a measurement model, wherein the measurement model simulates the DOE measurement signals generated by a nominal metrology system at each of the sets of values of the one or more system parameters, the nominal metrology system having the same nominal configuration as each of the fleet of metrology systems.

5. The method of claim 1, wherein the one or more metrology targets are device structures.

6. The method of claim 1, wherein the one or more metrology targets are specialized calibration structures.

7. The method of claim 1, further comprising:
adjusting a value of a system parameter associated with the first metrology system based on the estimated values of the one or more system parameters determined by the trained system parameter model.

8. The method of claim 7, wherein the adjusting of the value of the system parameter involves matching the value of the system parameter determined by the trained system parameter model.

9. The method of claim 7, wherein the adjusting of the value of the system parameter involves incrementally adjusting the value of the system parameter toward the value of the system parameter determined by the trained system parameter model.

10. The method of claim 1, further comprising:
estimating a set of one or more values of the one or more system parameters, wherein each element of the set of values corresponds to a measurement of a different instance of the one or more metrology targets at a different time; and
determining a tool health metric based on the set of the one or more values of the one or more system parameters.

11. A system, comprising:
an illumination source of a first metrology system of a fleet of metrology systems configured to provide a first amount of illumination light to a first instance of one or more metrology targets disposed on a first in-line, production wafer;
a detector of the first metrology system configured to detect a first amount of light from the first instance of the one or more metrology targets disposed on the first in-line, production wafer in response to the first amount of illumination light and generate a first set of measurement signals indicative of the first detected amount of light; and
one or more computing systems configured to:
estimate values of one or more system parameters associated with the first metrology system based on a trained system parameter model, wherein the trained system parameter model generates the estimated values of the one or more system parameters associated with the first metrology system based on the first set of measurement signals.

12. The system of claim 11, further comprising:
an illumination source of a second metrology system of the fleet of metrology systems configured to provide a second amount of illumination light to a second instance of the one or more metrology targets disposed on a second in-line, production wafer;
a detector of the second metrology system configured to detect a second amount of light from the second instance of the one or more metrology targets disposed on the second in-line, production wafer in response to the second amount of illumination light and generate a second set of measurement signals indicative of the second detected amount of light, the one or more computing systems further configured to:
estimate values of one or more system parameters associated with the second metrology system based on the trained system parameter model, wherein the trained system parameter model generates the estimated values of the one or more system parameters associated with the second metrology system based on the second set of measurement signals.

13. The system of claim 11, the one or more computing systems further configured to:
train the trained system parameter model, wherein the training is based on a set of Design Of Experiments (DOE) measurement data corresponding to the one or more metrology targets including multiple sets of measurement signals and corresponding sets of values of the one or more system parameters associated with each metrology system of the fleet of metrology systems.

14. The system of claim 13, wherein the DOE measurement signals are generated by simulation of a measurement model, wherein the measurement model simulates the DOE measurement signals generated by a nominal metrology system at each of the sets of values of the one or more system parameters, the nominal metrology system having the same nominal configuration as each of the fleet of metrology systems.

15. The system of claim 11, the one or more computing system further configured to:
adjust a value of a system parameter associated with the first metrology system based on the estimated values of the one or more system parameters determined by the trained system parameter model.

16. The system of claim 15, wherein the adjusting of the value of the system parameter involves matching the value of the system parameter determined by the trained system parameter model.

17. The system of claim 15, wherein the adjusting of the value of the system parameter involves incrementally adjusting the value of the system parameter toward the value of the system parameter determined by the trained system parameter model.

18. The system of claim 11, the one or more computing system further configured to:
estimate a set of one or more values of the one or more system parameters, wherein each element of the set of values corresponds to a measurement of a different instance of the one or more metrology targets at a different time; and
determine a tool health metric based on the set of the one or more values of the one or more system parameters.

19. The system of claim 11, wherein each metrology system of the fleet of metrology systems is a spectroscopic ellipsometer.

20. A system, comprising:
an illumination source of a first metrology system of a fleet of metrology systems configured to provide a first amount of illumination light to a first instance of one or more metrology targets disposed on a first in-line, production wafer;
a detector of the first metrology system configured to detect a first amount of light from the first instance of the one or more metrology targets disposed on the first in-line, production wafer in response to the first amount of illumination light and generate a first set of measurement signals indicative of the first detected amount of light; and
a non-transient, computer-readable medium storing instructions that, when executed by one or more processors, causes the one or more processors to:
estimate values of one or more system parameters associated with the first metrology system based on a trained system parameter model, wherein the trained system parameter model generates the estimated values of the one or more system parameters associated with the first metrology system based on the first set of measurement signals.
